(19) United States
(12) Patent Application Publication
(10) Pub. No.: US 2006/0141750 A1
(43) Pub. Date: Jun. 29, 2006

(54) Semiconductor integrated device and method for manufacturing same

(76) Inventors: Nobuhiro Suzuki, Osaka (JP); Kenji Imai, Osaka (JP); Isaya Kitamura, Osaka (JP); Keiichi Yamaguchi, Osaka (JP)

Correspondence Address: HOGAN & HARTSON L.L.P., 500 S. GRAND AVENUE, SUITE 1900, LOS ANGELES, CA, 90071-2611, US

(21) Appl. No.: 10/529,465

(22) PCT Filed: Nov. 12, 2003
(86) PCT No.: PCT/JP03/14363

§ 371 Date: Mar. 28, 2005

(30) Foreign Application Priority Data
Nov. 12, 2002 (JP) 2002-327663

(51) Int. Cl. H01L 21/78

(52) U.S. Cl. 438/460

(57) ABSTRACT

A method for manufacturing a semiconductor integrated device includes steps of forming an integrated circuit element on a semiconductor substrate, forming internal wiring, forming a groove along a scribe line on a back surface of the semiconductor substrate to expose a portion of the internal wiring, forming a metal film covering at least the groove, patterning the metal film to form external wiring and removing the metal film at a bottom portion of the groove, forming a protection film covering the external wiring and the bottom portion of the groove, and separating the semiconductor substrate along the scribe line.

### TECHNICAL FIELD

The present invention relates to a semiconductor integrated device having metal external wiring on a side surface of an element and a manufacturing method thereof.

### BACKGROUND ART

A chip size package (CSP) is employed in which external wiring extends to the outside from a side surface of an element in order to reduce a chip size of a semiconductor integrated device.

FIGS. 12A and 12B show external views of a semiconductor integrated device in which a chip size package is used. In general, in a semiconductor integrated device of a chip size package, a semiconductor chip 10 is sandwiched between an upper support substrate 14 and a lower support substrate 16 via a resin layer 12 such as epoxy and external wiring 18 extends to the outside from a side surface and is connected to a ball-shaped terminal 20 provided on a back surface of the element.

As shown in FIGS. 13-19, a semiconductor integrated device of the chip size package having such a structure is manufactured through a layered structure formation step (S10) of forming a layered structure in which the semiconductor chip 10 is sandwiched on both sides between the upper support substrate 14 and the lower support substrate 16 via the resin layer 12, a cutting step (S12) of cutting the layered structure from the side of the lower support substrate 16 with a dicing saw or the like in a “reverse V” shape to form a groove (cut groove) 24 to expose an end 28 of an internal wiring 26 of the semiconductor chip 10, a metal film formation step (S14) of forming a metal film 30 on an inner surface of the groove 24, a patterning step (S16) of patterning the metal film 30 to form external wiring 18 connecting the end 28 of the internal wiring 26 and a buffer member 32, a protection film formation step (S18) of forming a protection film 34, a terminal formation step (S20) of forming the ball-shaped terminal 20, and a dicing step (S22) of cutting a bottom portion of the groove 24 as a scribe line.

### DISCLOSURE OF INVENTION

In the semiconductor integrated device of chip size package manufactured through the related art, there had been a problem in that an end 36 of the external wiring 18 at the side surface of the element is not covered with the protection film 34 and corrosion from the outside of the element tends to develop.

As a result, there had been problems such as the external wiring 18 being easily peeled off from the side surface of the element, the contact resistance with the internal wiring 26 being increased, and the reliability of operation of the semiconductor integrated device being reduced.

In order to cover the end 36 of the external wiring 18 with a protection film after the dicing step (S22), it is necessary to perform a separate step of applying the protection film to each of the cut semiconductor integrated devices. Therefore, this configuration has caused a significant reduction in the throughput of manufacture.

The present invention was conceived in consideration of the problems of the related art described above and advantageously provides a semiconductor integrated device in which corrosion of external wiring present on a side surface of an element can be prevented and a manufacturing method thereof, to solve at least one of the problems described above.

According to one aspect of the present invention, there is provided a method for manufacturing a semiconductor integrated device, comprising a first step of forming an integrated circuit element in each region on a semiconductor substrate partitioned by a scribe line; a second step of forming internal wiring extending toward a boundary of adjacent integrated circuit elements; a third step of forming a groove along the scribe line on a back surface of the semiconductor substrate to expose a portion of the internal wiring; a fourth step of forming a metal film covering the back surface of the semiconductor substrate and the groove; a fifth step of patterning the metal film to form external wiring and removing the metal film at a bottom portion of the groove; a sixth step of forming a protection film covering the external wiring and the bottom portion of the groove; and a seventh step of separating the semiconductor substrate along the scribe line.

According to another aspect of the present invention, there is provided a semiconductor integrated device comprising a semiconductor chip in which an integrated circuit element is formed on a semiconductor substrate; internal wiring formed on the semiconductor substrate and extending to a side periphery of the semiconductor substrate; and external wiring formed detouring around a side surface of the semiconductor chip and connected to the internal wiring, wherein an end of the external wiring is covered by a protection film.

### BRIEF DESCRIPTION OF DRAWINGS

FIG. 1 is a diagram showing an integrated circuit element formation step according to a preferred embodiment of the present invention.

FIG. 2 is a diagram showing an internal wiring formation step according to a preferred embodiment of the present invention.

FIG. 3 is a diagram showing a layered structure formation step according to a preferred embodiment of the present invention.

FIG. 4 is a diagram showing a cutting step according to a preferred embodiment of the present invention.

FIG. 5 is a diagram showing a metal film formation step according to a preferred embodiment of the present invention.

FIG. 6 is a diagram showing a pattering step according to a preferred embodiment of the present invention.

FIG. 7 is a diagram showing a protection film formation step according to a preferred embodiment of the present invention.

FIG. 8 is a diagram showing a terminal formation step according to a preferred embodiment of the present invention.

FIG. 9 is a diagram showing a dicing step according to a preferred embodiment of the present invention.

FIG. 10 is a diagram showing removal of a metal film in the patterning step according to a preferred embodiment of the present invention.

FIG. 11 is a diagram enlarging an end of a semiconductor integrated device according to a preferred embodiment of the present invention.

FIGS. 12A and 12B are diagrams showing an external view of a semiconductor integrated device of a chip size package.

FIG. 13 is a diagram showing a layered structure formation step in a related art.

FIG. 14 is a diagram showing a cutting step in a related art.

FIG. 15 is a diagram showing a metal film formation step in a related art.

FIG. 16 is a diagram showing a patterning step in a related art.

FIG. 17 is a diagram showing a protection film formation step in a related art.

FIG. 18 is a diagram showing a terminal formation step in a related art.

FIG. 19 is a diagram showing a dicing step in a related art.

FIG. 20 is a diagram enlarging an end of a semiconductor integrated device in a related art.

### BEST MODE FOR CARRYING OUT THE INVENTION

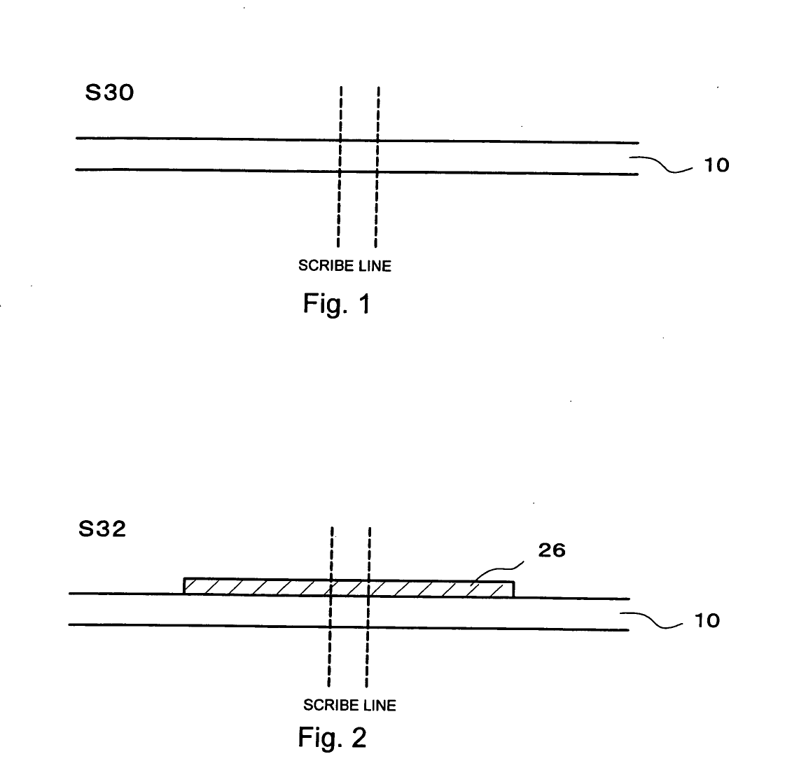

As shown in FIGS. 1-9, a method for manufacturing a semiconductor integrated device according to a preferred embodiment of the present invention basically has an integrated circuit element formation step (S30), an internal wiring formation step (S32), a layered structure formation step (S34), a cutting step (S36), a metal film formation step (S38), a patterning step (S40), a protection film formation step (S42), a terminal formation step (S44), and a dicing step (S46).

In the integrated circuit element formation step of step S30, an integrated circuit element is formed in each region of a semiconductor substrate (wafer) 10 partitioned by a scribe line as shown in FIG. 1. A material of the semiconductor substrate 10 may be a typical semiconductor material such as silicon and gallium arsenide and the integrated circuit element may be formed through known semiconductor processing.

As shown in FIG. 2, in the internal wiring formation step of step S32, internal wiring 26 is formed on a front surface of the semiconductor substrate 10 via an oxide film, extending toward a boundary of adjacent integrated circuit elements. The internal wiring 26 is electrically connected to the integrated circuit element through a contact hole formed through the oxide film.

As a material of the internal wiring 26, any material typically used for a semiconductor device may be used as a primary material, such as silver, gold, copper, aluminum, nickel, titanium, tantalum, and tungsten. In consideration of the electrical resistance and workability of the material, it is desirable to use aluminum. It is more preferable to use aluminum which contains copper in an amount of 0.1 atomic % or greater and 20 atomic % or less, in order to avoid corrosion from the outside of the element.

A thickness of the internal wiring 26 is preferably 1 μm or higher in order to reduce contact resistance with the external wiring to be formed later, and 10 μm or less in order to increase process precision of the wiring and shorten a film formation time.

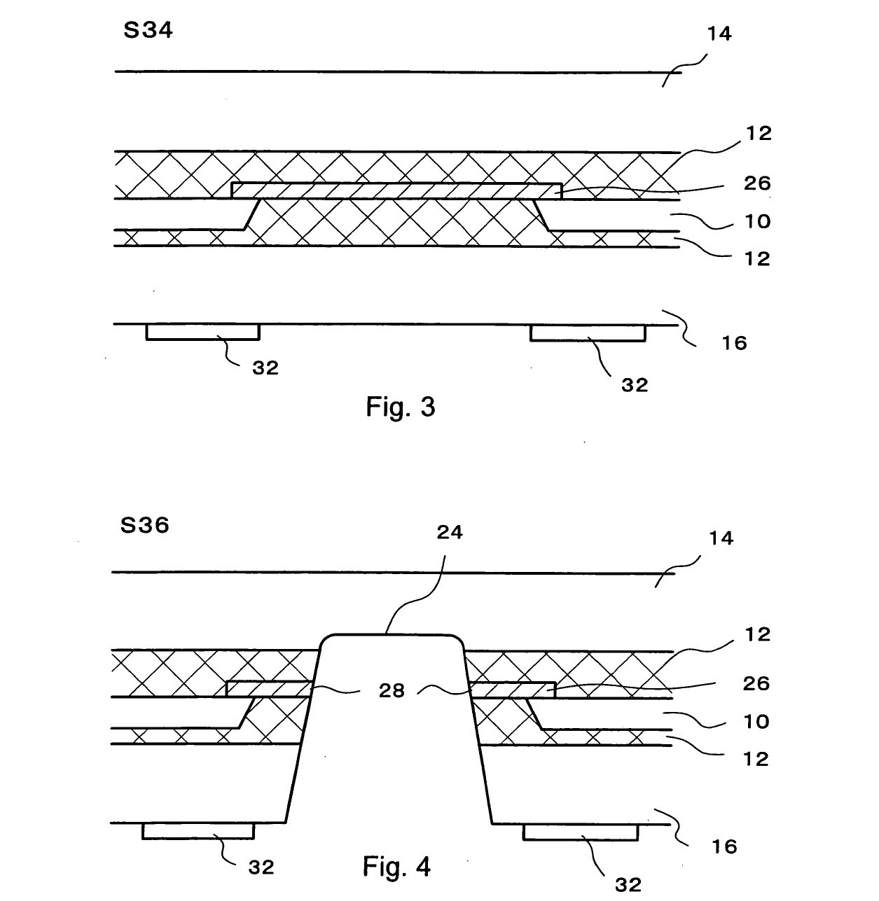

As shown in FIG. 3, in the layered structure formation step of step S34, a resin layer 12 such as an epoxy adhesive is applied to a front surface and a back surface of the semiconductor substrate 10 on which the integrated circuit element is formed, and the semiconductor substrate 10 is sandwiched by an upper support substrate 14 and a lower support substrate 16 to form a layered structure.

In this step, the semiconductor substrate 10 is ground through mechanical grinding or chemical grinding from the side of the back surface to reduce the thickness of the semiconductor substrate 10 and the semiconductor substrate 10 is etched along the scribe line from the side of the back surface to expose a surface of the oxide film on which the internal wiring 26 is layered.

The upper support substrate 14 and the lower support substrate 16 may be formed with a suitable selection of a material from among materials used in packaging of a semiconductor device such as glass, plastic, metal, or ceramic. For example, when a solid-state image sensing element is formed on a silicon substrate, it is preferable to select transparent glass or plastic as the upper support substrate.

Then, a buffer member 32 is formed on the surface of the lower support substrate 16 at a position where a ball-shaped terminal 20 will be formed in a later step. The buffer member 32 has a cushioning function to absorb stress applied to the ball-shaped terminal 20. As a material of the buffer member 32, a material which is flexible and which can be patterned is suitable, and a photosensitive epoxy resin is preferably used.

As shown in FIG. 4, in the cutting step of step S36, a groove (cutting groove) 24 is formed in a reverse V shape which reaches from the side of the lower support substrate 16 to the upper support substrate 14 using a dicing saw or the like. As a result of this step, an end 28 of the internal wiring 26 is exposed on an inner surface of the groove 24.

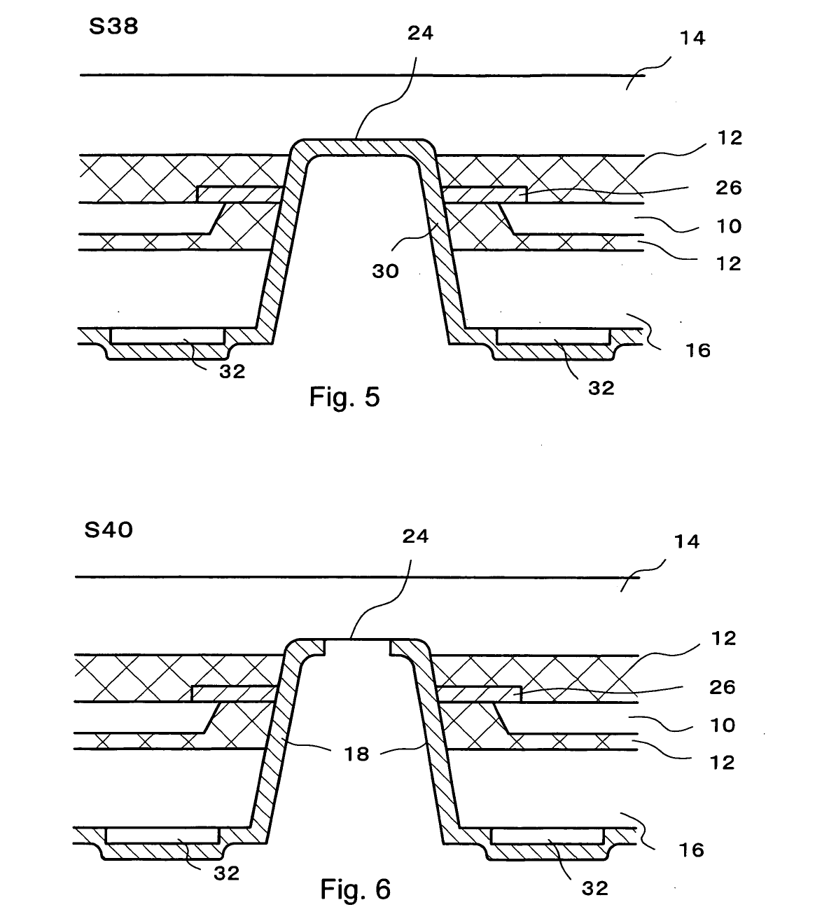

As shown in FIG. 5, in the metal film formation step of step S38, a metal film 30 is formed on the side of the lower support substrate on which the groove 24 is formed. The metal film 30 is formed also over a bottom surface and a side surface of the groove 24. The metal film 30 is processed in the patterning step which will be described below so that external wiring 18 for extending the internal wiring 26 to the outside is formed.

Regarding a material of the metal film 30, a material typically used for a semiconductor device may be used as the primary material, such as, for example, silver, gold, copper, aluminum, nickel, titanium, tantalum, and tungsten. In consideration of an electrical resistance and workability of the material, it is preferable to use aluminum. In order to avoid corrosion from the outside of the element, it is more preferable to use aluminum containing copper in a concentration of 0.1 atomic % or more and 20 atomic % or less.

As shown in FIG. 6, in the patterning step of step S40, the metal film 30 is patterned in a predetermined wiring pattern to process and form the shape of the external wiring 18. For this patterning, currently available photolithography and etching techniques may be employed.

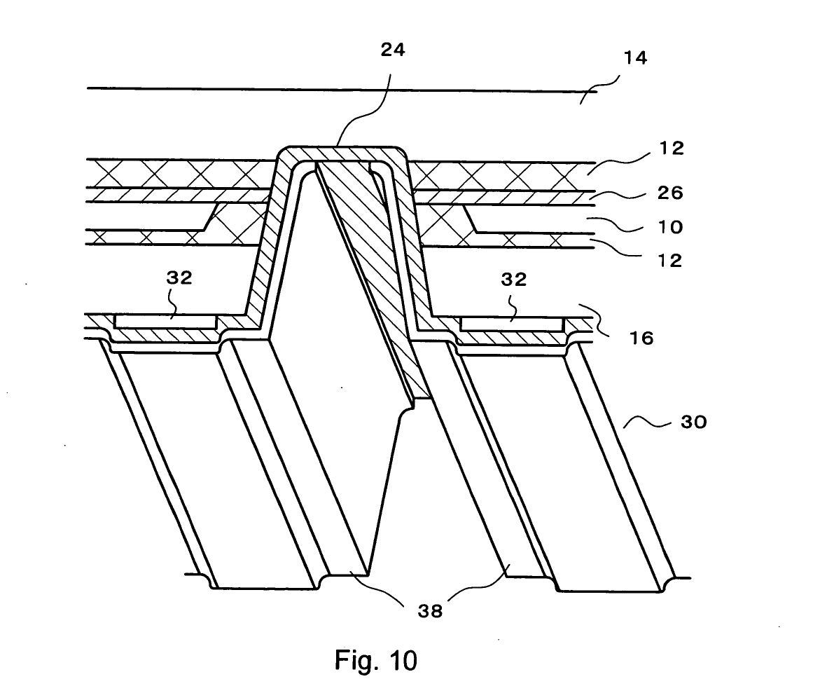

In step S40, simultaneous with the patterning, the metal film 30 formed on the bottom surface of the groove 24 is removed. Specifically, as shown in FIG. 10, a resist pattern 38 is formed covering portions other than the bottom portion of the groove 24 and etching is applied using the resist pattern 38 as a mask to remove the metal film 30 at the bottom of the groove 24.

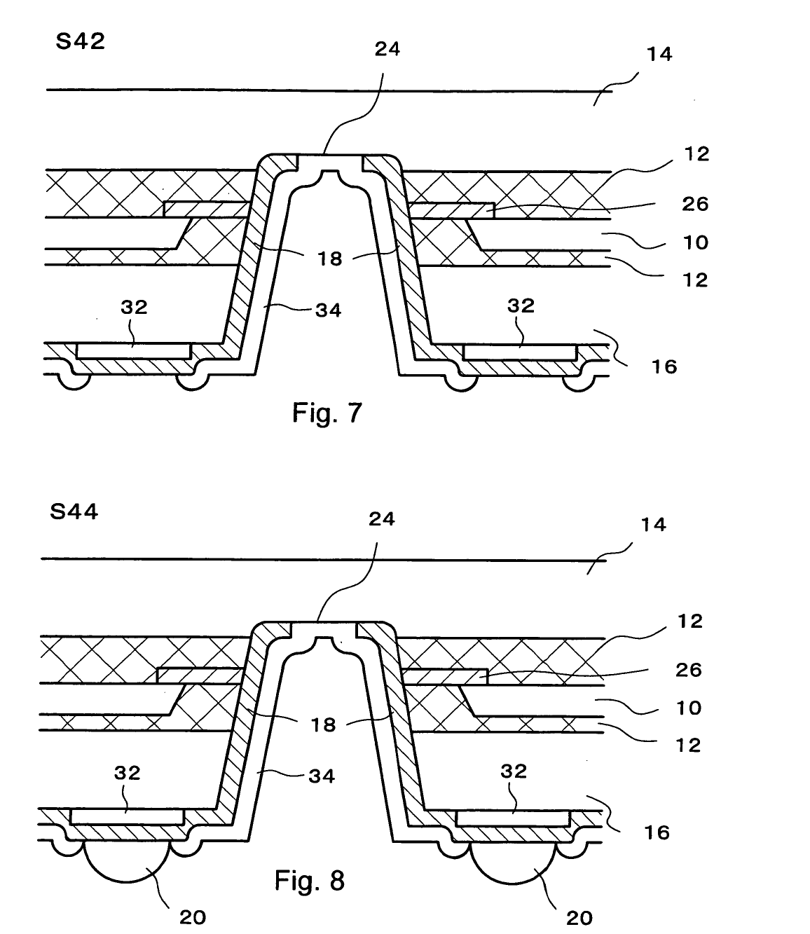

As shown in FIG. 7, in the protection film formation step of S42, a protection film 34 is formed to cover a region on the side of the lower support substrate other than the buffer member 32. Because a material which can be patterned is suitable for the protection film 34, it is possible to use photosensitive epoxy resin or the like similar to the material of the buffer member 32.

As shown in FIG. 8, in the terminal formation step of step S44, a ball-shaped terminal 20 is formed as an external terminal on the buffer member 32 of the lower support substrate 16. The ball-shaped terminal 20 is formed, for example, with solder and may be formed through an existing method.

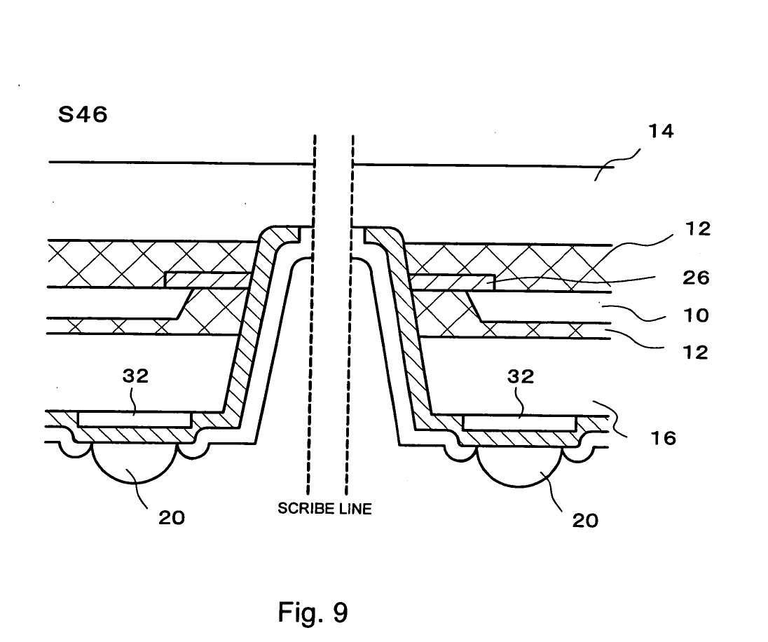

As shown in FIG. 9, in the dicing step of step S46, the layered structure is cut using a dicing saw or the like with the bottom of the groove 24 as the scribe line to separate the layered structure into individual semiconductor integrated device.

In this step, a dicing saw having a cutting width which is narrower than a removal width of the metal film 30 in the step S30 is selected and used. With such a configuration, the end 36 of the external wiring 18 is positioned internal to the side surface of the semiconductor integrated device after the separation, and therefore, the end 36 of the external wiring 18 is covered by a protection film 34. When a dicing saw having a narrower cutting width than the removal width of the metal film 30 cannot be selected, it is also possible to employ a configuration in which the metal film 30 is removed in a wider width in step S30.

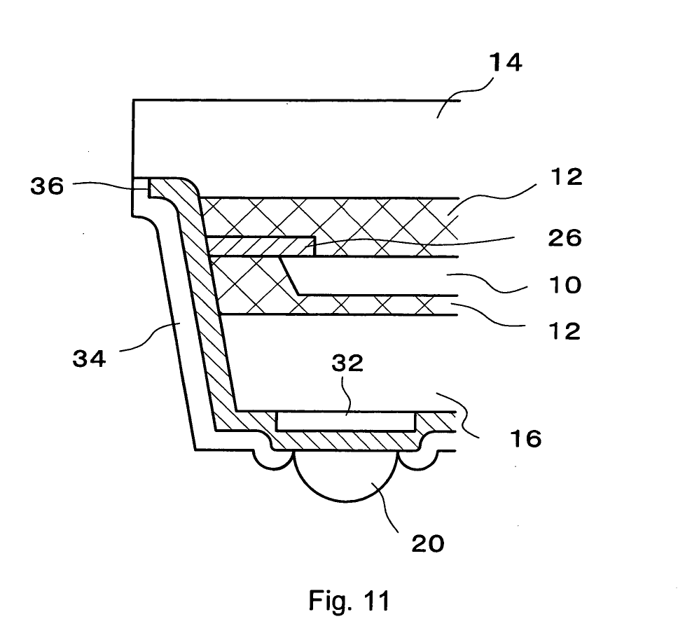

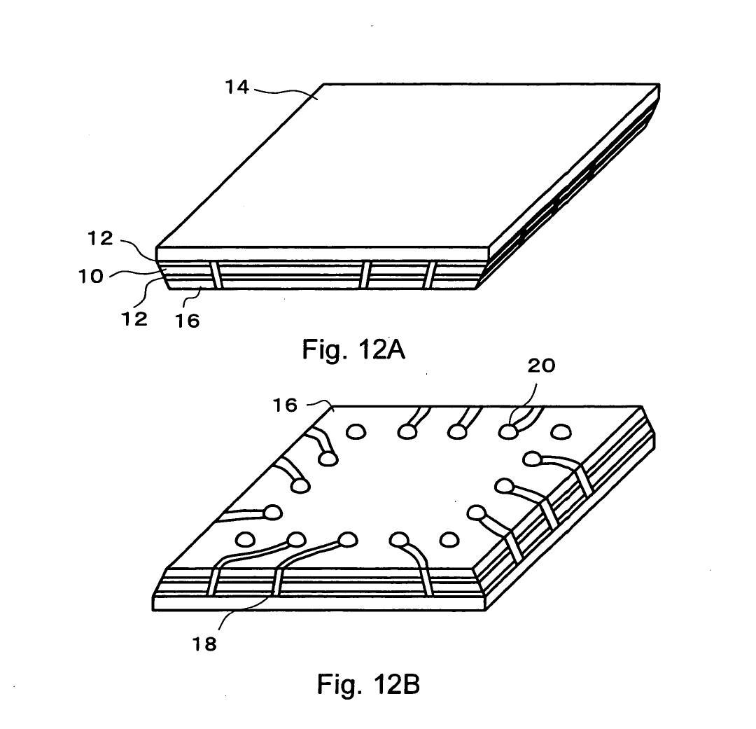

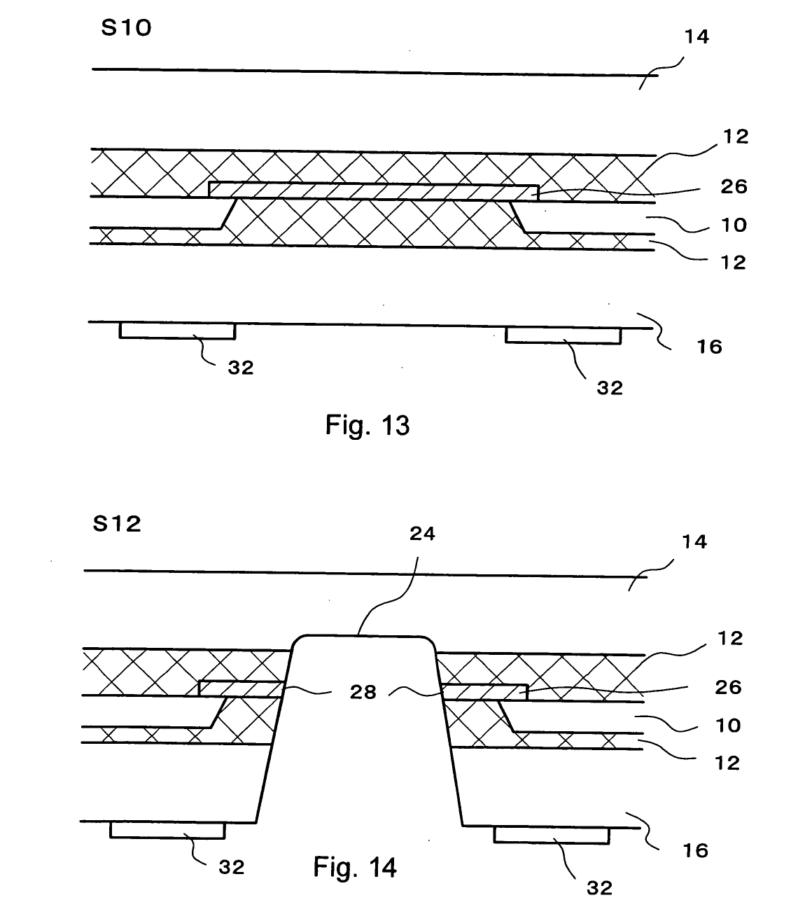

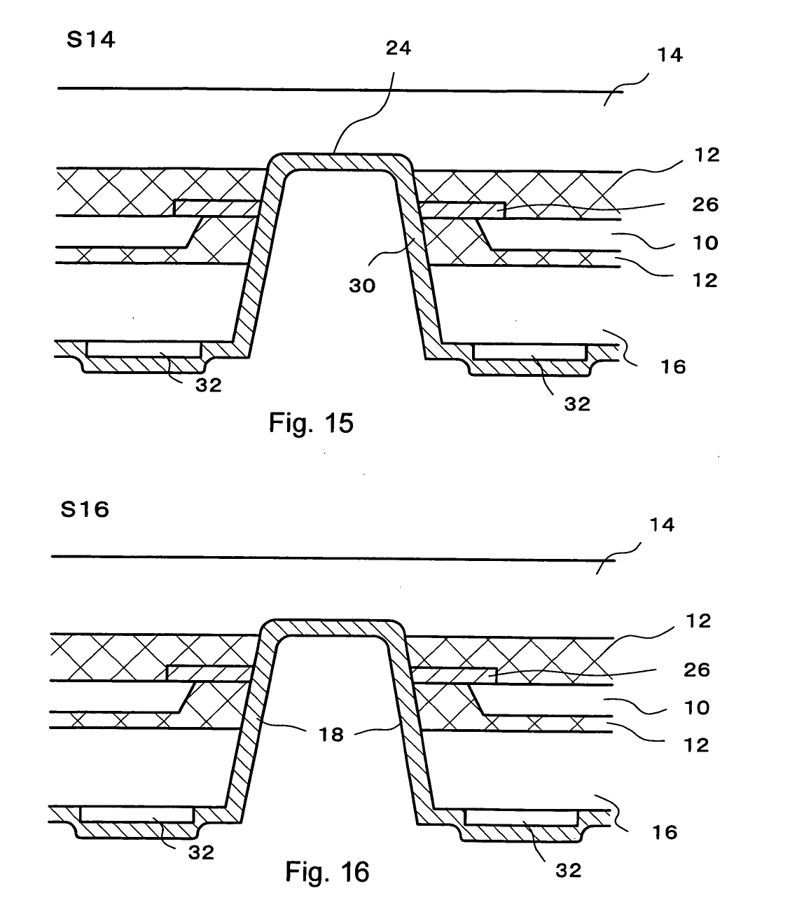

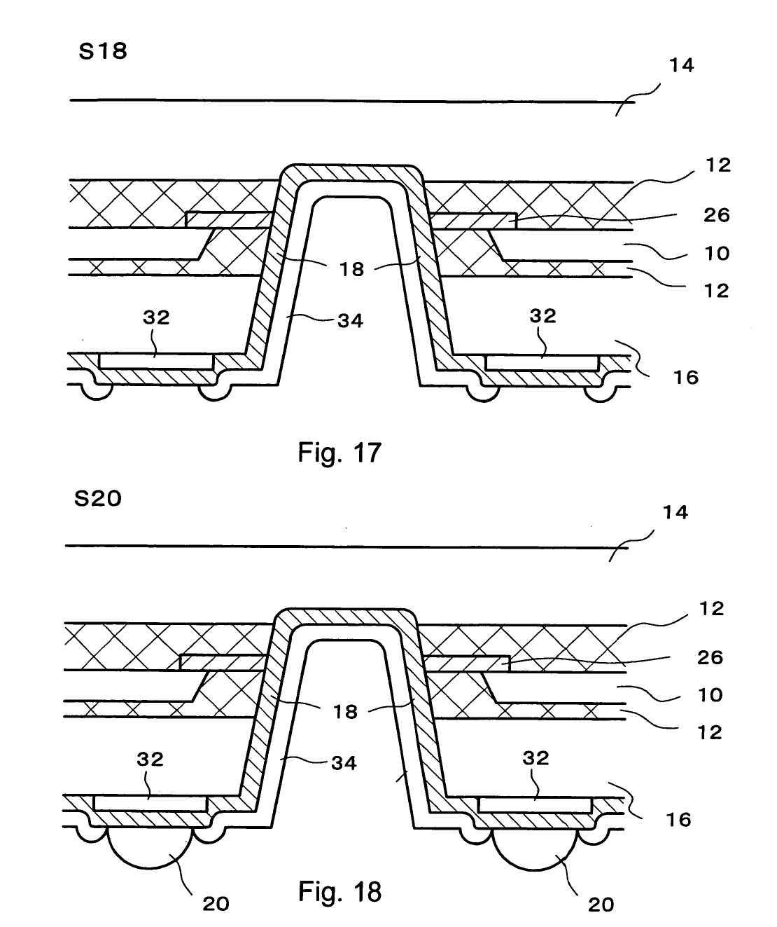

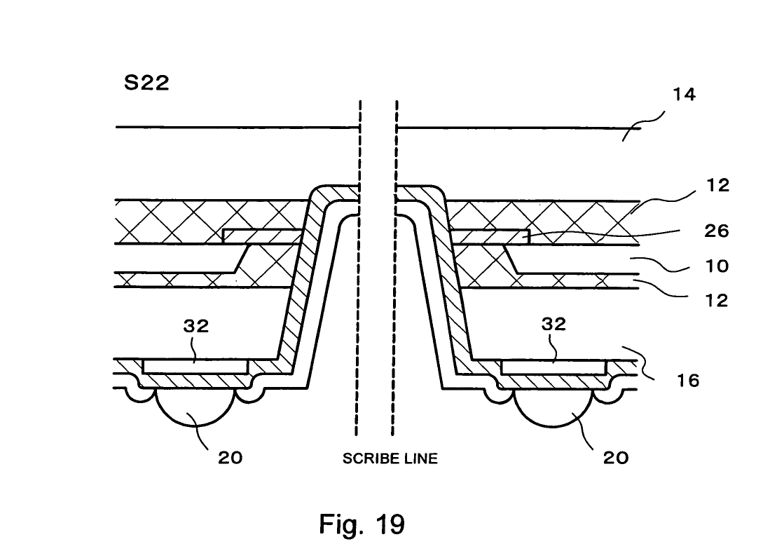

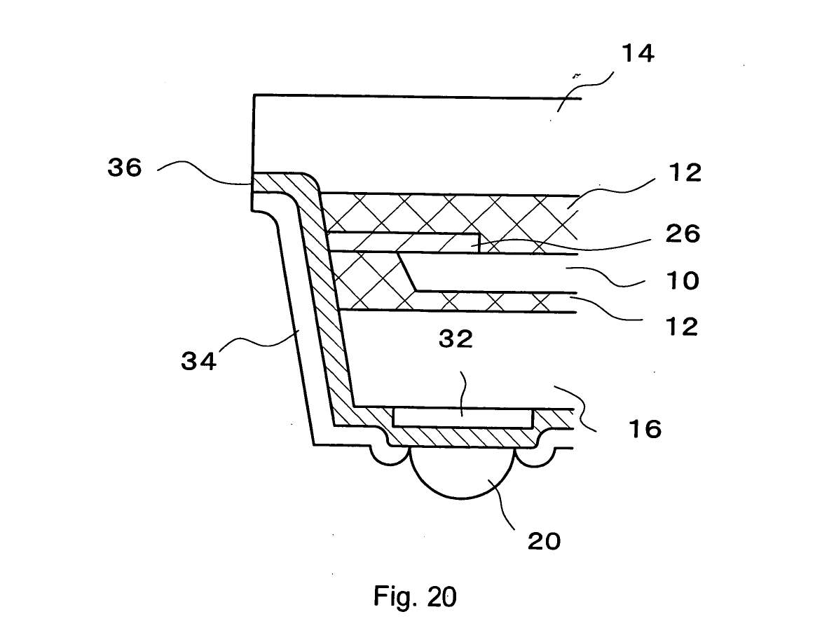

As described, according to a method for manufacturing a semiconductor integrated device of the preferred embodiment of the present invention, in a semiconductor integrated device of a chip size package having external wiring 18 on a side surface of the device, the end 36 of the external wiring 18 on the side surface of the device is completely covered by the protection film 34, as shown in an enlargement view of the end portion of FIG. 11.

Therefore, it is difficult for corrosion from the outside of the device to progress and it is possible to prevent peeling of the external wiring 18 and degradation of contact resistance between the external wiring 18 and the internal wiring 26. As a result, it is possible to improve reliability of operation of the semiconductor integrated device.

In addition, because it is not necessary to separately perform a process to apply a protection film to each of the semiconductor integrated devices, the throughput of the manufacturing process is not degraded.

In the preferred embodiment, the method has been described referring to a chip size package of a ball grid array (BGA) type, but the present invention is not limited to such a configuration and a similar structure can be obtained through a similar manufacturing process for any semiconductor integrated device having external wiring on the side surface of the element, resulting in similar advantages.

According to the present embodiment, it is possible to provide a semiconductor integrated device having external wiring on a side surface of an element and in which the wiring does not corrode without increasing the number of manufacturing steps, and a manufacturing method thereof.

1. A method for manufacturing a semiconductor integrated device, comprising:
a first step of forming an integrated circuit element in each region on a semiconductor substrate partitioned by a scribe line;
a second step of forming internal wiring extending toward a boundary of adjacent integrated circuit elements;
a third step of forming a groove along the scribe line on a back surface of the semiconductor substrate to expose a portion of the internal wiring;
a fourth step of forming a metal film covering the back surface of the semiconductor substrate and the groove;
a fifth step of patterning the metal film to form external wiring and removing the metal film at a bottom portion of the groove;
a sixth step of forming a protection film covering the external wiring and the bottom portion of the groove; and
a seventh step of separating the semiconductor substrate along the scribe line.

2. A method for manufacturing a semiconductor integrated device according to claim 1, wherein
in the seventh step, the semiconductor substrate is separated with a cutting width which is narrower than a width of the bottom portion of the groove.

3. A method for manufacturing a semiconductor integrated device according to claim 1, wherein
in the fifth step, the metal film on the bottom portion of the groove is removed in a width wider than a cutting width in a separation of the seventh step.

4. A semiconductor integrated device comprising:
a semiconductor chip in which an integrated circuit element is formed on a semiconductor substrate;
internal wiring formed on the semiconductor substrate and extending to a side periphery of the semiconductor substrate; and
external wiring formed detouring around a side surface of the semiconductor chip and connected to the internal wiring, wherein
an end of the external wiring is covered by a protection film.

5. A semiconductor integrated device according to claim 4, wherein
the end of the external wiring is positioned internal to a side surface of the semiconductor integrated device.

6. A semiconductor integrated device according to claim 4, wherein
the external wiring is made of aluminum to which copper is added.

7. A semiconductor integrated device according to claim 4, wherein
the internal wiring is made of aluminum to which copper is added.
